(19) United States
(12) Patent Application Publication
(10) Pub. No.: US 2016/0351156 A1
(43) Pub. Date: Dec. 1, 2016

(54) SHIFT REGISTER UNIT, GATE DRIVING CIRCUIT, DRIVING METHOD THEREOF AND DISPLAY PANEL

(71) Applicants: BOE TECHNOLOGY GROUP CO., LTD., Beijing (CN); SHENGDU BOE OPTOELECTRONICS TECHNOLOGY CO., LTD., Chengdu, Sichuan (CN)

(72) Inventors: Bo WU, Beijing (CN); Yin DENG, Beijing (CN); Xiaojing QI, Beijing (CN); Wen TAN, Beijing (CN)

(73) Assignees: Boe Technology Group Co., Ltd. et al.; Chengdu Boe Optoelectronics Technoology Co., Ltd.

(21) Appl. No.: 14/890,845

(22) PCT Filed: Mar. 13, 2015
(86) PCT No.: PCT/CN2015/074230

§ 371 Date: Nov. 12, 2015

(30) Foreign Application Priority Data
Nov. 12, 2014 (CN) 201410645991.9

(51) Int. Cl. G09G 3/36; G11C 19/28

(52) U.S. Cl. CPC G09G 3/3688; G11C 19/28; G09G 3/3677; G09G 2310/0286; G09G 2310/08; G09G 2300/0809

(57) ABSTRACT

A shift register unit, a gate driving circuit, a driving method thereof and a display panel, wherein the shift register unit includes an input module, a pulling-down module, a control module, an output pulling-up module and an output pulling-down module. In the shift register unit, each module performs only a specified voltage pulling-up function or a specified voltage pulling-down function, and therefore it can be formed with only N-type TFTs or only P-type TFTs. As compared with the known CMOS LTPS GOA, the shift register unit and gate driving circuit has a simple structure, is easy to be implemented, has full functions, possesses high performance and reliability and the like, which are benefit for reduction of the cost along with the popularization and application of the CMOS LTPS GOA.

### TECHNICAL FIELD

The present disclosure relates to a field of display technique, and particularly to a shift register unit, a gate driving circuit, a driving method thereof and a display panel.

### BACKGROUND

Currently, the Complementary Metal Oxide Semiconductor (CMOS) Low Temperature Poly-silicon (LTPS) technique is generally applied to a Liquid Crystal Display (LCD). A gate driving circuit integrated with the CMOS process has a simple structure, and has advantages of high reliability, low power consumption, etc. However, in the traditional CMOS process, both of P-type Thin Film Transistors (TFTs) and N-type TFTs coexist, so both of the performance requirements for the N-type TFTs and the P-type TFTs have to be satisfied in order to ensure a functionality and the reliability of the circuit during a manufacture process, such that a complex and difficulty of the LTPS process is increased, the performance and yield ratio of the is decreased, the product cost is raised, which restricts application of the CMOS LTPS GOA (Gate Driver on Array).

For example, FIG. 1 illustrates a CMOS LTPS GOA circuit, wherein this GOA circuit includes latches, NAND gates, buffers, etc. The GOA circuit would comprise tens of transistors and the connection therebetween would be very complex if the components therein are implemented by modules including TFTs. Further, both the performance of the N-type transistors and that of the P-type transistors in the circuit should be satisfied in order to ensure functionality and reliability of the circuit, such that difficulty in process is increased

### SUMMARY

In view of this, the present disclosure provides a shift register unit, a gate driving circuit, a driving method thereof and a display panel. According to embodiments of the present disclosure, the LTPS GOA circuit can be manufactured with a single N-Mental-Oxide-Semiconductor (NMOS) process or a single P-Mental-Oxide-Semiconductor (PMOS) process, and therefore complexity and difficulty of the LTPS process are decreased, performance and yield ratio of the TFTs are improved and cost of product is reduced, which is benefit for the popularization and application of the CMOS LTPS GOA.

According to a first aspect, the present disclosure provides a shift register unit, comprising:

an input module, connected with an input terminal, a reset terminal and a first node, configured to pull up or pull down a voltage at the first node under controls of a signal from the input terminal, a signal from the reset terminal, a first external scan control signal and a second external scan control signal;

an output pulling-up module, connected with the input module via the first node and connected with an output terminal, configured to pull up a voltage at the output terminal under controls of the voltage at the first node and the first external clock signal;

a pulling-down module, connected with a second node and a low level voltage line and connected with the input module via the first node, configured to pull down the voltage at the first node under a control of a voltage at the second node;

a control module, connected with the first node via the input module, connected with the pulling-down module via the second node and connected with the low level voltage line, configured to pull up or pull down the voltage at the second node under the controls of the voltage at the first node and the second external clock signal; and

an output pulling-down module, connected with the second node, the low level voltage line, the input terminal, the reset terminal and the output terminal, configured to pull down the voltage at the output terminal under the controls of the signal from the input terminal, the signal from the reset terminal and the voltage at the second node.

Optically, transistors in the shift register unit are all N-type transistors or P-type transistors.

Optically, the output pulling-up module comprises a first transistor and a first capacitor, wherein a gate of the first transistor is connected with the first node, a drain thereof is connected with the first external clock signal, and a source thereof is connected with the output terminal; a first terminal of the first capacitor is connected with the first node and a second terminal thereof is connected with the output terminal.

Optically, the input module comprises a second transistor and a third transistor,

wherein a gate of the second transistor is connected with the input terminal, a drain thereof is connected with the first external scan control signal and a source thereof is connected with the first node; and

a gate of the third transistor is connected with the reset terminal, a drain thereof is connected with the first node and a source thereof is connected with the second external scan control signal.

Optically, the pulling-down module comprises a sixth transistor,

a gate of the sixth transistor is connected with the second node, a drain thereof is connected with the first node, and a source thereof is connected with the low level voltage line.

Optically, the output pulling-down module comprises a seventh transistor, an eighth transistor and a ninth transistor, wherein

a gate of the seventh transistor is connected with the second node, a drain thereof is connected with the output terminal and a source thereof is connected with the low level voltage line;

a gate of the eighth transistor is connected with the input terminal, a drain thereof is connected with the output terminal and a source thereof is connected with the low level voltage line; and

a gate of the ninth transistor is connected with the reset terminal, a drain thereof is connected with the output terminal and a source thereof is connected with the low level voltage line.

Optically, the control module comprises a fourth transistor, a fifth transistor and a second capacitor, wherein

a gate and a drain of the fourth transistor are connected with the second external clock signal, and a source thereof is connected with the second node;

a gate of the fifth transistor is connected with the first node, a drain thereof is connected with the second node and a source thereof is connected with the low level voltage line; and

a first terminal of the second capacitor is connected with the second node, and a second terminal is connected with the low level voltage line.

Optically, the control module further comprises a tenth transistor,

a gate and a drain of the tenth transistor are connected with a scan start signal, and a source thereof is connected with the second node.

According to a second aspect, the present disclosure further provides a gate driving circuit comprising at least one of stages of shift register units described above; wherein

a first external scan control signal line is configured to supply the first external scan control signal to each of stages of shift register units, and a second external scan control signal line is configured to supply the second external scan control signal to each of the stages of shift register units;

a first clock signal line is configured to supply a first external clock signal to odd-numbered stages of shift register units, a second clock signal line is configured to supply the first external clock signal to even-numbered stages of shift register units, a third clock signal line is configured to supply a second external clock signal to the odd-numbered stages of shift register units, and a fourth clock signal line is configured to supply the second external clock signal to the even-numbered stages of shift register units;

the input terminal of the first stage of shift register unit and the reset terminal of the last stage of shift register unit are connected with the scan start signal; besides that,

the input terminal of each of remaining stages of shift register units is connected with the output terminal of its corresponding previous stage of shift register unit, and the reset terminal of each of remaining stages of shift register units is connected with the output terminal of its corresponding next stage of shift register unit.

According to a third aspect, the present disclosure further provides a driving method applied to any one of gate driving circuits described above, and the gate driving method comprises:

during a forward scanning, the first external scan control signal is at a constant high level, the second external scan control signal is at a constant low level, and the signals on the first to fourth clock signal lines are square wave signals with same cycle but phase lagging ¼ cycle to each other sequentially;

during a backward scanning, the first external scan control signal is at the constant low level, the second external scan control signal is at the constant high level, and the signals on the first to fourth clock signal lines are square wave signals with same cycle but the phase leading ¼ cycle to each other sequentially.

According to a fourth aspect, the present disclosure further provides a display panel comprising any one of gate driving circuits described above.

With the above solutions, in the shift register unit according to the present disclosure, each module performs only a specified pulling-up voltage function or a specified pulling-down voltage function, and therefore it can be formed with only N-type TFTs or only P-type TFTs. As compared with the known CMOS LTPS GOA, the shift register unit and gate driving circuit according to the present disclosure has simple structure, is easy to be implemented, has full function, and possesses high performance and reliability, which are benefit for reduction of the cost along with the popularization and application of the CMOS LTPS GOA.

Of course, any product or method which is implemented with the present disclosure is not necessary to achieve all advantages above at the same time.

### BRIEF DESCRIPTION OF THE DRAWINGS

In order to explain solutions in embodiments of the present disclosure or the prior art more clearly, drawings required as describing the embodiments of the present disclosure or the prior art will be introduced briefly below. Obviously, the drawings described below only illustrate some embodiments of the present disclosure, but those ordinary skilled in the art may obtain other drawings according to these drawings without paying any inventive labors.

FIG. 1 is a circuit diagram illustrating a known CMOS LIPS GOA circuit;

FIG. 2 is an exemplary view illustrating a structure of a shift register unit according to an embodiment of the present disclosure;

FIG. 3 is a circuit diagram illustrating a shift register unit according to an embodiment of the present disclosure;

FIG. 4 is a circuit timing diagram of a shift register unit during the forward scanning according to an embodiment of the present disclosure;

FIG. 5 is a circuit timing diagram of a shift register unit during the backward scanning according to an embodiment of the present disclosure;

FIG. 6 is a block diagram illustrating a cascade connection of respective stages of shift register units in a gate driving circuit according to an embodiment of the present disclosure;

FIG. 7 is a circuit timing diagram of a driving method for a gate driving circuit during the forward scanning according to an embodiment of the present disclosure;

FIG. 8 is a circuit timing diagram of a driving method for a gate driving circuit during the backward scanning according to an embodiment of the present disclosure; and

FIG. 9 is a circuit diagram illustrating a shift register unit according to an embodiment of the present disclosure.

### DETAILED DESCRIPTION

Thereafter, solutions of embodiments of the present disclosure will be described clearly and completely in connection with drawings of the embodiments of the present disclosure for the purpose of illustrating the object, technical solutions and advantages of the embodiments of the present disclosure more clearly, but obviously the described embodiments are only some, but not all of the embodiments of the present disclosure. Any other embodiments obtained by those ordinary skilled in the art based on the embodiments of the present disclosure without inventive labors should fall into a scope sought for protection in the present disclosure.

It should be noted that, as used in the present disclosure, the orientation or position relationship indicated by the terms “up”, “down”, etc., are the orientation or position relationship illustrated in drawings, which is only used to facilitate the description of the present disclosure and simplify the description, rather than indicate or suggest that a device or element must have a specific orientation, be configured or operate in the specific orientation, therefore it can not be constructed as any limitations on the present disclosure. Unless otherwise specified, the term “install”, “connect”, “wired” should be understand broadly and generally, for example, it may be a fixed connection, a detachable connection, or a integrated connection, may be a mechanical connection or an electrically connection; may be connected directly or connected via intervening elements; or may also be an internal connection between two components. For those ordinary skilled in the art, the specific meaning of the above terms in the present disclosure may be understood based on their specific context.

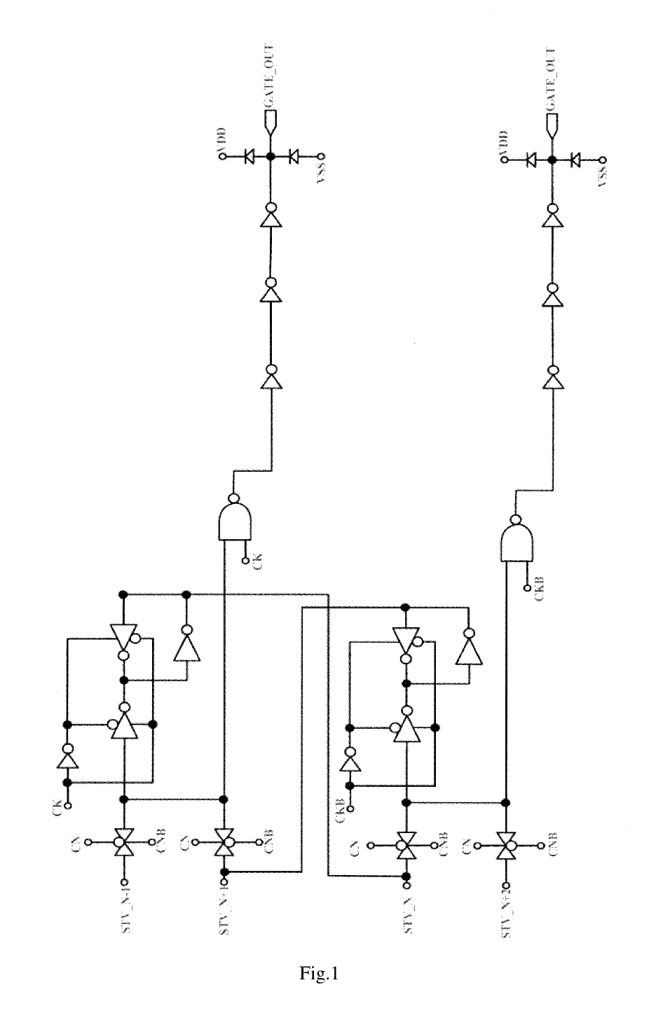

FIG. 1 illustrates a circuit diagram of a known CMOS LTPS GOA. Wherein STV_N−1 is an output signal of a (N−1)th stage of GOA unit, STV_N is an output signal of a Nth stage of GOA unit, and STV_N+1 is an output signal of a (N+1)th stage of GOA unit; the import of the STV_N−1, STV_N and STV_N+1 is controlled by the first external scan control signal CN and a second external scan control signal CNB control; the GOA circuit may cause the output terminal GATE_OUT of the current stage of GOA unit to output a high level or a low level based on voltages supplied from a high level voltage line VDD and a low level voltage line VSS, under the triggering of the clock signals CK and CKB.

It can be seen that this GOA circuit includes latches, NAND gates, buffers, etc., The GOA circuit would comprise tens of transistors (generally, both N type transistors and P type transistors are required) and the connection therebetween would be very complex if the components therein are implemented by modules including TFTs. Further, both the performance of the N-type transistors and that of the P-type transistors in the circuit should be satisfied in order to ensure functionality and reliability of the circuit, such that difficulty in process is increased.

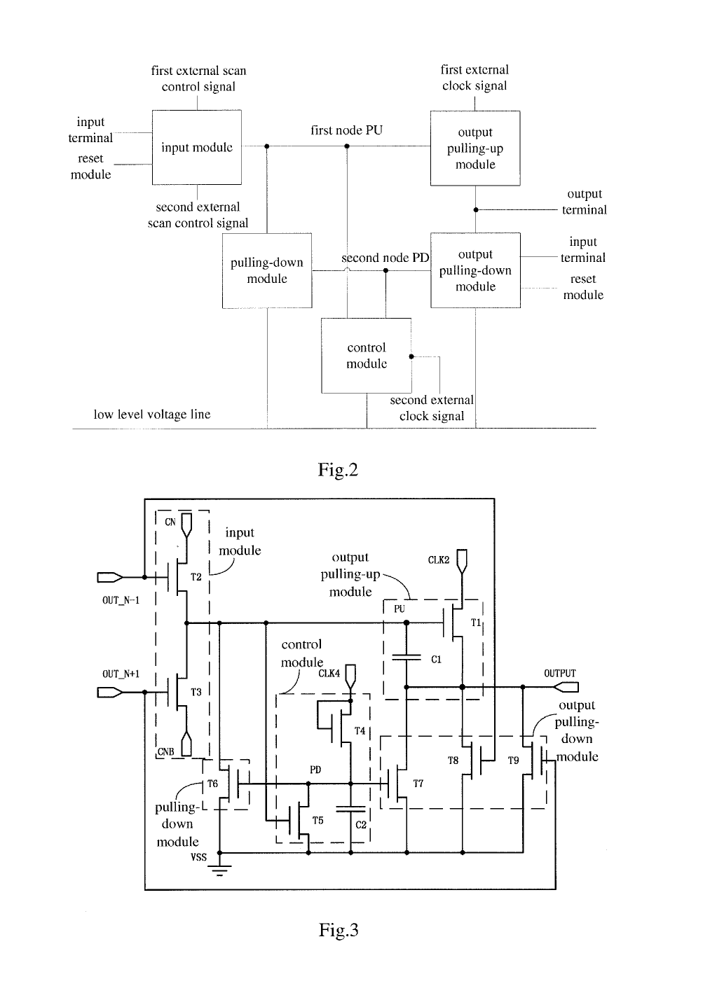

In view of this, an embodiment of the present disclosure provides a shift register unit. Referring to a structure of the shift register unit illustrated in FIG. 2, the shift register unit comprises:

an input module, connected with an input terminal, a reset terminal and a first node PU, configured to pull up or pull down a voltage at the first node PU under controls of a signal from the input terminal, a signal from the reset terminal, a first external scan control signal and a second external scan control signal;

an output pulling-up module, connected with the input module through the first node PU and with an output terminal, configured to pull up a voltage at the output terminal under controls of the voltage at the first node PU and the first external clock signal;

a pulling-down module, connected with a second node PD and a low level voltage line and with the input module through the first node PU, configured to pull down the voltage at the first node PU under a control of a voltage at the second node;

a control module, connected with the first node PU through the input module, with the pulling-down module through the second node PD and with the low level voltage line, configured to pull up or pull down the voltage at the second node PD under the controls of the voltage at the first node PU and the second external clock signal; and

an output pulling-down module, connected with the second node PD, the low level voltage line, the input terminal, the reset terminal and the output terminal, configured to pull down the voltage at the output terminal under the controls of the voltage from the input terminal, the signal from the reset terminal and the voltage at the second node PD.

Thus, in the shift register unit according to the present disclosure, each module performs only a specified voltage pulling-up function or a specified voltage pulling-down function, therefore each can be implemented by only N-type TFTs or only P-type TFTs. As compared with the CMOS LTPS GOA circuit illustrated in FIG. 1, the shift register unit according to the present disclosure has simple structure, is easy to be implemented, has full function, and possesses high performance and reliability, which are benefit for reduction of the cost along with the popularization and application of the CMOS LTPS GOA.

More particular, solutions according to the embodiments of the present disclosure would be explained by taking a shift register unit as an example. Referring to the circuit diagram of a shift register unit illustrated in FIG. 3, the shift register unit also comprises parts such as the input module, the output pulling-up module, the output pulling-down module, control module and the like.

Optionally, the output pulling-up module comprises a first transistor T1 and a first capacitor C1, wherein a gate of the first transistor T1 is connected with the first node PU, a drain thereof is connected with the first external clock signal CLK2 and a source thereof is connected with the output terminal; a first terminal of the first capacitor C1 is connected with the first node PU and a second terminal thereof is connected with the output terminal.

Optionally, the input module comprises a second transistor T2 and a third transistor T3, wherein a gate of the second transistor T2 is connected with the input terminal, a drain thereof is connected with the first external scan control signal CN and a source thereof is connected with the first node PU; and a gate of the third transistor T3 is connected with the reset terminal, a drain thereof is connected with the first node PU and a source thereof is connected with the second external scan control signal CNB.

Optionally, the pulling-down module comprises a sixth transistor T6, wherein a gate of the sixth transistor T6 is connected with the second node PD, a drain thereof is connected with the first node PU, and a source thereof is connected with the low level voltage line VSS.

Optionally, the output pulling-down module comprises a seventh transistor T7, an eighth transistor T8 and a ninth transistor T9, wherein a gate of the seventh transistor T7 is connected with the second node PD, a drain thereof is connected with the output terminal and a source thereof is connected with the low level voltage line VSS; a gate of the eighth transistor T8 is connected with the input terminal, a drain thereof is connected with the output terminal and a source thereof is connected with the low level voltage line VSS; and a gate of the ninth transistor T9 is connected with the reset terminal, a drain thereof is connected with the output terminal and a source thereof is connected with the low level voltage line VSS.

Optionally, the control module comprises a fourth transistor T4, a fifth transistor T5 and a second capacitor C2, wherein a gate and a drain of the fourth transistor T4 are connected with the second external clock signal CLK4, and a source thereof is connected with the second node PD; a gate of the fifth transistor T5 is connected with the first node PU, a drain thereof is connected with the second node PD and a source thereof is connected with the low level voltage line VSS; and a first terminal of the second capacitor C2 is connected with the second node PD, and a second terminal is connected with the low level voltage line VSS.

Particularly, the input module comprises the second transistor T2 and the third transistor T3, and controls to implement a forward scanning or a backward scanning and pre-charge or reset the gate of the first transistor T1 and the first node PU, according to the first external scan control signal CN, the second external scan control signal CNB, the signal OUT_N−1 from the input terminal and the signal OUT_N+1 from the reset terminal (the input terminal and the reset terminal may be exchanged); the output pulling-up module comprises the first transistor T1 and the first capacitor C1, and makes the output terminal to be at the high level in cooperation with the clock signals after the pre-charging; the output pulling-down module comprises the seventh transistor T7, the eighth transistor T8 and the ninth transistor T9, and pulls down a potential at the output terminal under the control of the signal from the second node PD, the signal OUT_N−1 from the input terminal and the signal OUT_N+1 from the reset terminal, during the phase for maintaining the low level output; the pulling-down module comprises the sixth transistor T6, and pulls down a potential at the first node PU under the control of the signal from the second node PD; the control module comprises the fourth transistor T4, the fifth transistor T5 and the second capacitor C2, and controls the potential at the second node PD under the control of the clock signals and the potential at the first node PU, particularly controls the potential at the second node PD to be at the low level during a pre-charging phase and a phase for pulling-up output, while controls the potential at the second node PD to be at the high level during the phase for outputting a low level.

The first external scan control signal CN and the second external scan control signal CNB are configured to implement a bi-direction scan of the shift register unit. Specifically, an operational timing diagram of the above circuit during the forward scanning is illustrated as FIG. 4, and its operational principle would be explained below.

Phase a is the pre-charging phase. During this phase, the output OUT_N−1 of the previous stage of GOA is received by the input terminal of the current stage of GOA, the terminal OUT_N−1 is at the high level VGH (a potential at the low level voltage line is at VGL), the transistor T2 is turned on, and the node PU is pre-charged by the high level on the CN to the high level; the transistor T5 is turned on, the node PD is discharged and pulled down to the low level; the transistors T6 and T7 are turned off; the gate of the transistor T8 is connected with the terminal OUT_N−1 and the transistor T8 is turned on, and the terminal OUTPUT is pulled down. The output OUT_N+1 of the next stage of GOA is received by the reset terminal of the current stage of GOA, and the transistors T3 and T9 are turned off when the OUT_N+1 is at the low level, therefore the capacitor C1 is pre-charged to VGH-VGL.

Phase b is a phase for pulling up the output. During this phase, the signal OUT_N−1 from the input terminal is at the low level, the transistor T2 is turned off, and the transistor T8 is turned off; the signal OUT_N+1 from the reset terminal is at the low level, and the transistors T3 and T9 are turned off; none of the node PU and the terminal OUTPUT is pulled down. Because the signal CK4 as CLK4, is still at the low level, the node PU is at the high level, the transistor T5 is still turned on; the node PD is still maintained to be at the low level VGL, and the transistors T6 and T7 are kept in their turn-off states. The voltage across the capacitor C1 is maintained as VGH-VGL; the signal CK2 as the CLK2 is changed to be the high level VGH from the low level, therefore the gate of the transistor T1 (i.e. the node PU) is coupled to a higher level 2VGH-VGL through the first capacitor Cl, then the potential at the terminal OUTPUT is pulled up to the high level VGH via the transistor T1 (that is, a function of boost-up is realized).

Phase c is a reset phase wherein the output OUT_N+1 from the next stage of GOA is at the high level, so that the transistor T3 is turned on, the node PU is pulled down to the low level VGL, and the transistor T5 is turned off; the transistor T9 is turned on, and the OUTPUT is pulled down to the low level VGL.

Phase d is a direct current pulling-down phase. During this phase, both of the terminals OUT_N−1 and OUT_N+1 are at the low levels, the transistors T2, T3, T8 and T9 are turned off. The node PU is still at the low level, the transistor T5 is kept to be off. The signal CK4 is at the high level and charges the capacitor C2, the node PD is pulled up to the high level VGH, and the capacitor C2 is charged to VGH-VGL. During a period in which the signals CK1, CK2 and CK3 are all at the high level, the high level at the node PD is maintained by means of the capacitor C2, the transistors T6 and T7 continue to be turned on, and the potentials at the node PU and the terminal OUTPUT are pulled down in a manner of direct current pulling-down.

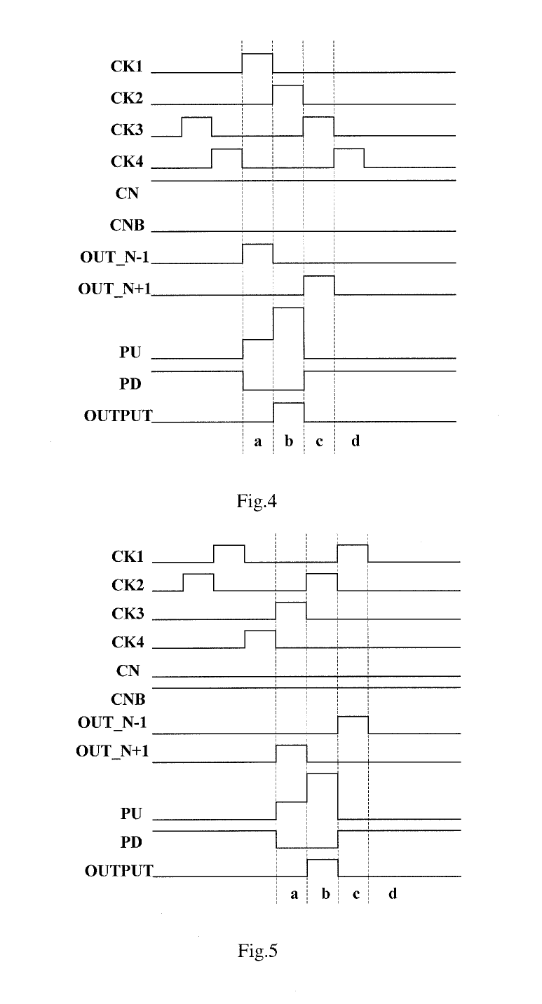

On the other hand, during the backward scanning, the CN is at the low level VGL, the CNB is at the high level VGH, the clocks CK1, CK2, CK3 and CK4 scan in backward mode, the GOA is in a backward scanning state, the input terminal and the reset terminal are exchanged. The operational timing diagram of the above circuit is illustrated as FIG. 5, and its operational principle would be explained below.

Phase a is the pre-charging phase. During this phase, the output OUT_N+1 of the next stage of GOA is the start signal, the terminal OUT_N+1 is at the high level VGH, and the transistor T3 is turned on; the node PU is pre-charged by the high level on the terminal CNB to the high level VGH, the transistor T5 is turned on; the node PD is discharged and pulled down to the low level, and the transistors T6 and T7 are turned off; the gate of the transistor T9 is connected with the terminal OUT_N+1 and the transistor T9 is turned on, the terminal OUTPUT is pulled down. The output OUT_N−1 of the previous stage of GOA is at the low level, the transistors T2 and T8 are turned off; therefore the voltage across the capacitor C1 is pre-charged to VGH-VGL.

Phase b is the phase for pulling-up output. During this phase, the start signal OUT_N+1 is at the low level, the transistor T3 is turned off, and the transistor T9 is turned off; the signal OUT_N−1 from the previous stage of GOA is at the low level, the transistors T2 and T8 are turned off, and none of the node PU and the terminal OUTPUT is pulled down. Because the signal CK4 as the CLK4, is still at the low level, the node PU is at the high level, the transistor T5 is still turned on; the node PD is still maintained to be at the low level VGL, and the transistors T6 and T7 are kept in their turn-off status. The voltage across the capacitor C1 is maintained as VGH-VGL; the signal CK2 as CLK2, is changed to be the high level VGH from the low level, and therefore the gate of the transistor T1(i.e., the node PU) is coupled to a higher level 2VGH-VGL through the first capacitor C1, then the potential at the OUTPUT is pulled up to the high level VGH via the T1 (that is, a function of boost-up is realized).

Phase c is the reset phase. During this phase, the output OUT_N−1 from the previous stage of GOA is at the high level, so that the transistor T2 is turned on, the node PU is pulled down to the low level, and the transistor T5 is turned off; the transistor T8 is turned on, and the terminal OUTPUT is pulled down to the low level VGL.

Phase d is the direct current pulling-down phase. During this phase, both of the terminals OUT_N−1 and OUT_N+1 are at the low levels, the transistors T2, T3, T8 and T9 are turned off. The node PU is still at the low level, the transistor T5 is maintained to be low level. The terminal CK4 is at the high level and the capacitor C2 is charged, and the node PD is pulled up to the high level VGH; the capacitor C2 is charged to VGH-VGL. During a period in which the signals CK3, CK2 and CK1 are all at the high level, the high level at the node PD is maintained by means of the capacitor C2, the transistors T6 and T7 continue to be turned on, and the potentials at the node PU and terminal OUTPUT are pulled down in a manner of direct current pulling-down.

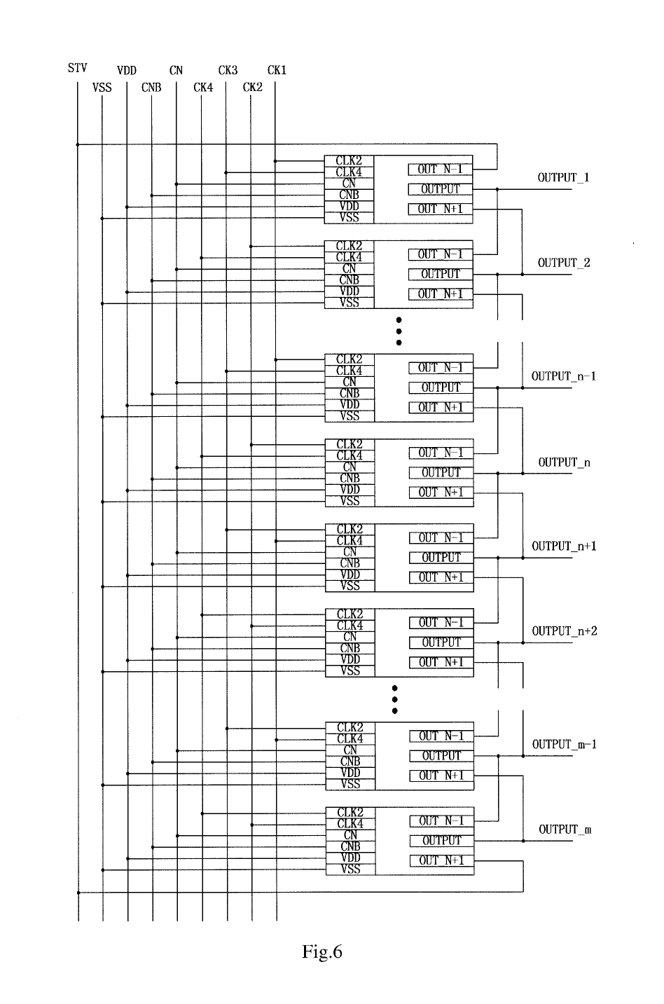

In a case where a gate driving circuit (the GOA circuit) is formed with the shift register units described above, as illustrated in FIG. 6, the GOA units are connected in cascade to form the gate driving circuit; the gate driving circuit operates under the four clock signals CK1, CK2, CK3 and CK4, which are square wave signals with same period and phases leading or lagging ¼ period with each other sequentially; the gate driving circuit comprises at least one stage of shift register units described above, and has output terminals OUTPUT_1, OUTPUT_2, . . . , OUTPUT_n−1, OUTPUT_n, OUTPUT_n+1, OUTPUT_n+2, OUTPUT_m−1, OUTPUT_m.

Further, the first external scan control signal line supplies the first external scan control signal CN to each of stages of shift register units, and the second external scan control signal line supplies the second external scan control signal CNB to each of the stages of shift register units;

the first clock signal line CK1 supplies the first external clock signal CLK2 to odd-numbered stages of shift register units, the second clock signal line CK2 supplies the first external clock signal CLK2 to even-numbered stages of shift register units, the third clock signal line CK3 supplies the second external clock signal CLK4 to the odd-numbered stages of shift register units, and the fourth clock signal line CK4 supplies the second external clock signal CLK4 to the even-numbered stages of shift register units;

the input terminal of the first stage of shift register unit and the reset terminal of the last stage of shift register unit are connected with the scan start signal STV;

the input terminal OUT_N−1 of each of other stages of shift register units is connected with the output terminal OUTPUT of its previous stage of shift register unit, and the reset terminal OUTPUT_N+1 of each of other stages of shift register units is connected with the output terminal OUTPUT of its next stage of shift register unit.

Particularly, when the GOA circuit operates in the above process, during the forward scanning, the output from the present stage of GOA unit provides the input signal of the next stage of GOA unit, and the output of the next stage of GOA unit provides the reset signal of the present stage of GOA unit; during the backward scanning, the output from the next stage of GOA unit provides the input signal of the present stage of GOA unit, the output of the present stage of GOA unit provides the reset signal of the next stage of GOA unit.

The shift register unit (GOA unit) and the gate driving circuit (GOA circuit) described above have a simple structure, and further have features of, for example, the direct current pulling-down, the bi-direction scan, triggering with four clock signals, no floating in the output signal, the boost-up, wherein the bi-direction scan is important for a LCD with small size, the GOA with four clocks is suitable for a high resolution LCD product. Further, the single NMOS process or the single PMOS process can be applied, the manufacture process is simpler, the production efficiency is higher, the performance is more reliable, and the number of the transistors adopted in the circuit is less, which is benefit for the narrow bezel design of the LCD product.

For any one of the gate driving circuits described above, there is further provided a driving method for the gate driving circuit, and the driving method would be explained below.

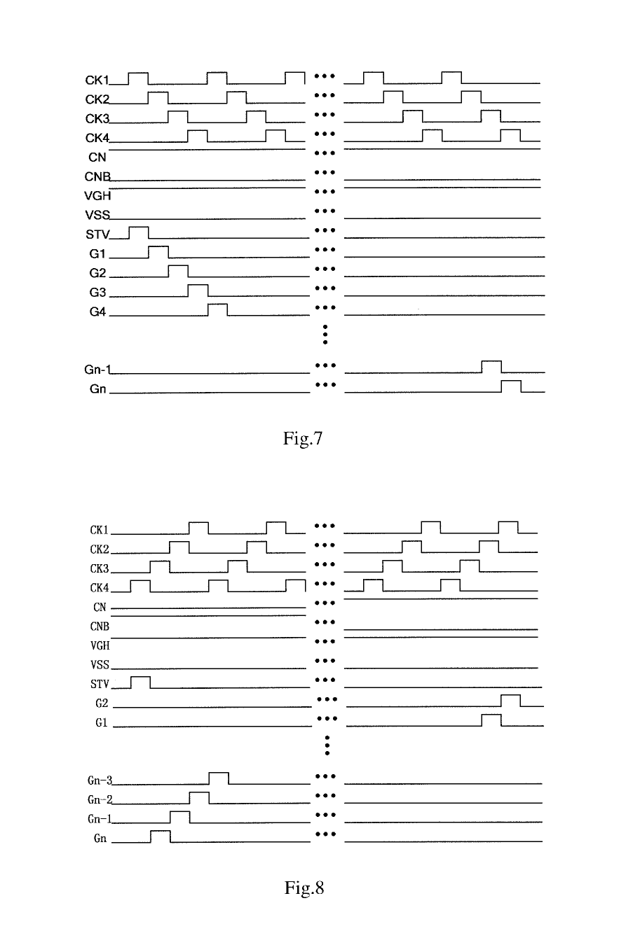

Referring to the circuit timing diagram of the gate driving circuit during the forward scanning as illustrated in FIG. 7, during the forward scanning, the first external scan control signal CN is at a constant high level, the second external scan control signal CNB is at a constant low level, and the signals on the first to fourth clock signal lines CK1 to CK4, are square wave signals with a same period but phases lagging ¼ period with each other sequentially.

Referring to the circuit timing diagram of the gate driving circuit during the backward scanning as illustrated in FIG. 8, during the backward scanning, the first external scan control signal CN is at the constant low level, the second external scan control signal CNB is at the constant high level, and the signals on the first to fourth clock signal lines, CK1 to CK4, are square wave signals with a same period but phases leading ¼ period with each other sequentially.

Under the effect of the above signals, in accordance with the scan start signal STV, the outputs G1, G2, Gn−1, Gn (n is a positive integer being no less than 1) of the respective stages of shift register units shifts forward or backward sequentially (the detailed shifting process in each shift register unit may be referred to the operational principle of the shift register unit during the forward scanning and the backward scanning described above), as illustrated in FIGS. 7 and 8.

The driving method for the gate driving circuit can be applied to any one of the gate driving circuits described above, therefore the same technical problem can be solved and the same technical effect can be achieved.

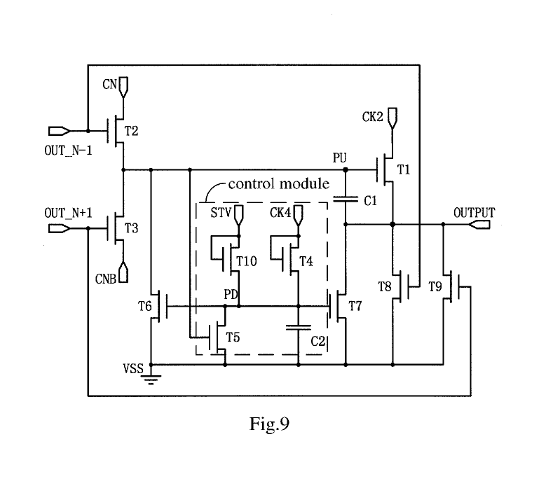

Furthermore, FIG. 9 illustrates a circuit diagram of another control module according to another embodiment of the present disclosure. In this embodiment, a tenth transistor T10, whose gate and drain are connected with the scan start signal STV and source is connected with the second node PD, is further provided, so that all of the nodes PD in the GOA circuit is charged to VGH while all the nodes PU and all the terminals OUTPUT in the GOA circuit are pulled down and reset at the same time upon each frame starts, thus a better reliability can be achieved.

Of course, any one of circuits described above is only the example of the shift register unit according to the embodiments of the present disclosure, those skilled in the art can also obtain other input module, pulling-down module, control module, output pulling-up module or output pulling-down module with any suitable structures based on these examples without departing from the spirit and scope of the embodiments of the present disclosure.

According to another aspect, there is further provided a display panel comprising any one of gate driving circuit described above, the display panel may be: electrical paper, a mobile phone, a tablet computer, a TV, a notebook computer, a digital photo frame, a navigator and any other product or part having the display function.

The display panel comprises any one of the gate driving circuits described above, therefore the same technical problem can be solved and the same technical effect can be achieved.

It should be noted that, as used herein, the relationship terms, such as first, second, etc., are only used to distinguish one entity or operation from another, rather than indicating or suggesting any actual relationship or order among these entities or operations. The term “include”, “comprise” or any other variety is intended to cover non exclusive inclusion, thereby the process, method, article or device including/comprising a series of elements includes/comprises not only those elements, but also other elements that are not explicitly listed, or also includes/comprises elements inherent to the process, method, article or equipment. In case where there is no more restriction, the element defined by a statement “includes/comprises one ” does not preclude other similar elements existed in the process, method, article or equipment.

It may understand that above implementations are only illustrative implementations utilized for explaining the principle of the present disclosure; however, the present disclosure is not limited thereto. Although it is described in detail as above, those ordinary skilled in the art should understand that many variations may be made to the solution as illustrated in the above embodiments or the equivalent replacements can be made to some of technical features therein without departing from the spirit and essence of the present disclosure, and such variations or replacements fall into the protection scope of the present disclosure.

This application claims priority to a Chinese Patent Application No. 201410645991.9, filed on Nov. 12, 2014, in the China's Patent Office, the disclosure of which is incorporated by reference herein as a whole.

1. A shift register unit, comprising:
an input module, connected with an input terminal, a reset terminal and a first node, configured to pull up or pull down a voltage at the first node under controls of a signal from the input terminal, a signal from the reset terminal, a first external scan control signal and a second external scan control signal;
an output pulling-up module, connected with the input module via the first node and connected with an output terminal, configured to pull up a voltage at the output terminal under controls of the voltage at the first node and the first external clock signal;
a pulling-down module, connected with a second node and a low level voltage line and connected with the input module via the first node, configured to pull down the voltage at the first node under a control of a voltage at the second node;
a control module, connected with the first node via the input module, connected with the pulling-down module via the second node and connected with the low level voltage line, configured to pull up or pull down the voltage at the second node under the controls of the voltage at the first node and the second external clock signal; and
an output pulling-down module, connected with the second node, the low level voltage line, the input terminal, the reset terminal and the output terminal, configured to pull down the voltage at the output terminal under the controls of the voltage from the input terminal, the signal from the reset terminal and the voltage at the second node.

2. The shift register unit of claim 1, wherein the output pulling-up module comprises a first transistor and a first capacitor, wherein a gate of the first transistor is connected with the first node, a drain thereof is connected with the first external clock signal, and a source thereof is connected with the output terminal; a first terminal of the first capacitor is connected with the first node, and a second terminal thereof is connected with the output terminal.

3. The shift register unit of claim 1, wherein the input module comprises a second transistor and a third transistor, wherein
a gate of the second transistor is connected with the input terminal, a drain thereof is connected with the first external scan control signal and a source thereof is connected with the first node; and
a gate of the third transistor is connected with the reset terminal, a drain thereof is connected with the first node, and a source thereof is connected with the second external scan control signal.

4. The shift register unit of claim 1, wherein the pulling-down module comprises a sixth transistor, wherein
a gate of the sixth transistor is connected with the second node, a drain thereof is connected with the first node, and a source thereof is connected with the low level voltage line.

5. The shift register unit of claim 1, wherein the output pulling-down module comprises a seventh transistor, an eighth transistor and a ninth transistor, wherein
a gate of the seventh transistor is connected with the second node, a drain thereof is connected with the output terminal, and a source thereof is connected with the low level voltage line;
a gate of the eighth transistor is connected with the input terminal, a drain thereof is connected with the output terminal, and a source thereof is connected with the low level voltage line; and
a gate of the ninth transistor is connected with the reset terminal, a drain thereof is connected with the output terminal, and a source thereof is connected with the low level voltage line.

6. The shift register unit of claim 1, wherein the control module comprises a fourth transistor, a fifth transistor and a second capacitor, wherein
a gate and a drain of the fourth transistor are connected with the second external clock signal, and a source thereof is connected with the second node;
a gate of the fifth transistor is connected with the first node, a drain thereof is connected with the second node, and a source thereof is connected with the low level voltage line; and
a first terminal of the second capacitor is connected with the second node, and a second terminal is connected with the low level voltage line.

7. The shift register unit of claim 6, wherein the control module further comprises a tenth transistor, wherein
a gate and a drain of the tenth transistor are connected with a scan start signal, and a source thereof is connected with the second node.

8. The shift register unit of claim 2, wherein transistors in the shift register unit are all N-type transistors or P-type transistors.

9. A gate driving circuit comprising at least one of stages of shift register units of claim 1; wherein
a first external scan control signal line is configured to supply the first external scan control signal to each of stages of shift register units, and a second external scan control signal line is configured to supply the second external scan control signal to each of the stages of shift register units;
a first clock signal line is configured to supply a first external clock signal to odd-numbered stages of shift register units, a second clock signal line is configured to supply the first external clock signal to even-numbered stages of shift register units, a third clock signal line is configured to supply a second external clock signal to the odd-numbered stages of shift register units, and a fourth clock signal line is configured to supply the second external clock signal to the even-numbered stages of shift register units;
the input terminal of the first stage of shift register unit and the reset terminal of the last stage of shift register unit are connected with the scan start signal; besides that,
the input terminal of each of remaining stages of shift register units is connected with the output terminal of its corresponding previous stage of shift register unit, and the reset terminal of each of remaining stages of shift register units is connected with the output terminal of its corresponding next stage of shift register unit.

10. A driving method applied to the gate driving circuit of claim 9, wherein the driving method comprises:
during a forward scanning, the first external scan control signal is at a constant high level, the second external scan control signal is at a constant low level, and the signals on the first to fourth clock signal lines are square wave signals with a same cycle but phases lagging ¼ cycle to each other sequentially; and
during a backward scanning, the first external scan control signal is at the constant low level, the second external scan control signal is at the constant high level, and the signals on the first to fourth clock signal lines are square wave signals with a same cycle but the phases leading ¼ cycle to each other sequentially.

11. A display panel comprising the gate driving circuit of claim 9.

12. The gate driving circuit of claim 9, wherein the output pulling-up module comprises a first transistor and a first capacitor, wherein a gate of the first transistor is connected with the first node, a drain thereof is connected with the first external clock signal, and a source thereof is connected with the output terminal; a first terminal of the first capacitor is connected with the first node, and a second terminal thereof is connected with the output terminal.

13. The gate driving circuit of claim 9, wherein the input module comprises a second transistor and a third transistor, wherein
a gate of the second transistor is connected with the input terminal, a drain thereof is connected with the first external scan control signal and a source thereof is connected with the first node; and
a gate of the third transistor is connected with the reset terminal, a drain thereof is connected with the first node, and a source thereof is connected with the second external scan control signal.

14. The gate driving circuit of claim 9, wherein the pulling-down module comprises a sixth transistor, wherein
a gate of the sixth transistor is connected with the second node, a drain thereof is connected with the first node, and a source thereof is connected with the low level voltage line.

15. The gate driving circuit of claim 9, wherein the output pulling-down module comprises a seventh transistor, an eighth transistor and a ninth transistor, wherein
a gate of the seventh transistor is connected with the second node, a drain thereof is connected with the output terminal, and a source thereof is connected with the low level voltage line;
a gate of the eighth transistor is connected with the input terminal, a drain thereof is connected with the output terminal, and a source thereof is connected with the low level voltage line; and
a gate of the ninth transistor is connected with the reset terminal, a drain thereof is connected with the output terminal, and a source thereof is connected with the low level voltage line.

16. The gate driving circuit of claim 9, wherein the control module comprises a fourth transistor, a fifth transistor and a second capacitor, wherein
a gate and a drain of the fourth transistor are connected with the second external clock signal, and a source thereof is connected with the second node;
a gate of the fifth transistor is connected with the first node, a drain thereof is connected with the second node, and a source thereof is connected with the low level voltage line; and
a first terminal of the second capacitor is connected with the second node, and a second terminal is connected with the low level voltage line.

17. The gate driving circuit of claim 16, wherein the control module further comprises a tenth transistor, wherein
a gate and a drain of the tenth transistor are connected with a scan start signal, and a source thereof is connected with the second node.

18. The display panel of claim 11, wherein the output pulling-up module comprises a first transistor and a first capacitor, wherein a gate of the first transistor is connected with the first node, a drain thereof is connected with the first external clock signal, and a source thereof is connected with the output terminal; a first terminal of the first capacitor is connected with the first node, and a second terminal thereof is connected with the output terminal.

19. The display panel of claim 11, wherein the input module comprises a second transistor and a third transistor, wherein
a gate of the second transistor is connected with the input terminal, a drain thereof is connected with the first external scan control signal and a source thereof is connected with the first node; and
a gate of the third transistor is connected with the reset terminal, a drain thereof is connected with the first node, and a source thereof is connected with the second external scan control signal.

20. The display panel of claim 11, wherein the pulling-down module comprises a sixth transistor, wherein
a gate of the sixth transistor is connected with the second node, a drain thereof is connected with the first node, and a source thereof is connected with the low level voltage line.
